(19) United States
(12) Patent Application Publication
(10) Pub. No.: US 2014/0306344 A1
(43) Pub. Date: Oct. 16, 2014

(54) WIRING STRUCTURE, SEMICONDUCTOR DEVICE INCLUDING WIRING STRUCTURE, AND METHOD OF MANUFACTURING SEMICONDUCTOR DEVICE

(71) Applicants: Shigetoshi Sugawa, Sendai-shi (JP); Akinobu Teramoto, Sendai-shi (JP); Rihito Kuroda, Sendai-shi (JP); Gu Xun, Sendai-shi (JP)

(72) Inventors: Shigetoshi Sugawa, Sendai-shi (JP); Akinobu Teramoto, Sendai-shi (JP); Rihito Kuroda, Sendai-shi (JP); Gu Xun, Sendai-shi (JP)

(73) Assignee: Tohoku University, Sendai-shi (JP)

(21) Appl. No.: 14/313,026

(22) Filed: Jun. 24, 2014

Related U.S. Application Data
(63) Continuation of application No. PCT/JP2012/052158, filed on Jan. 31, 2012.

(30) Foreign Application Priority Data
Dec. 28, 2011 (JP) 2011-289791

(51) Int. Cl. H01L 23/48; H01L 21/768

(52) U.S. Cl. CPC H01L 23/481; H01L 21/76843; H01L 21/76802
USPC 257/751; 438/653

(57) ABSTRACT

There is provided with a wiring structure. The wiring stracture has a damascene wiring structure including a metal wiring. The metal wiring is provided in direct contact with an upper surface of a barrier film (SiC(O, N) film) containing silicon (Si), carbon (C), and at least one of oxygen (O) and nitrogen (N) as constituent components.

This application is a continuation of International Patent Application No. PCT/JP2012/052158 filed on Jan. 31, 2012, and claims priority to Japanese Patent Application No. 2011-289791 filed on Dec. 28, 2011, the entire content of both of which is incorporated herein by reference.

### BACKGROUND OF THE INVENTION

1. Field of the Invention

The present invention relates to a wiring structure, a semiconductor device including the wiring structure, and a method of manufacturing the semiconductor device.

2. Description of the Related Art

In recent years, a Cu wiring is used as a wiring provided in a semiconductor device or the like in order to reduce the resistance and attain high reliability. Since it is difficult to form a Cu wiring by dry etching, a damascene wiring structure including multiple wiring layers is normally formed. The damascene wiring structure is formed by depositing Cu on an interlayer dielectric film having a trench structure as a wiring pattern and then removing Cu deposited outside the trench structure by chemical mechanical polishing (to also be referred to as “CMP” hereinafter) while leaving Cu in the trench structure.

In a particularly fine Cu wiring structure, for example, the insulating properties in the interlayer dielectric film may degrade due to diffusion of Cu. Hence, a barrier metal configured to prevent diffusion of Cu is known to be inserted between the Cu wiring and the interlayer dielectric film. As the barrier metal, for example, Ta (tantalum) or TaN (tantalum nitride) that is a compound thereof is used.

On the other hand, as the interlayer dielectric film, a CF film (in the present application, one or both of a perfluorocarbon film and a partially fluorine-substituted hydrocarbon film will sometimes generically be referred to as a “CF film”) that is a compound of carbon (C) and fluorine (F) is known to be used. When forming a Cu wiring in a single-layer or multilayer wiring structure substrate or a semiconductor device, a heat treatment process such as annealing is executed at, for example, about 250° C. to 350° C. In this heat treatment process, fluorine (F) derived from the CF film may diffuse in the barrier metal film. At this time, for example, when the barrier metal is made of tantalum (Ta) or tantalum nitride (TaN), TaF₅ (tantalum fluoride) is formed in the barrier metal.

TaF₅ readily vaporizes during the above-described heat treatment process because the vapor pressure is very high. When the vaporization occurs, the Ta density in the barrier metal film may lower, and the Cu diffusion prevention effect may weaken. As a result, a leakage current may increase, resulting in a defective wiring structure substrate or semiconductor device. In addition, adhesion between the CF film and the barrier metal film may lower, resulting in film peeling.

As a solution to this problem, Japanese Patent Laid-Open No. 2008-4841 (PTL 1) discloses a semiconductor device including a first film that is, for example, a Ti (titanium) film to prevent diffusion of fluorine (F) from a CF film, and a second film that is, for example, a Ta (tantalum) film to prevent diffusion of Cu from a Cu wiring. U.S. Patent Application Publication No. 2006/0113675 (PTL 2) discloses a damascene Cu wiring structure including a barrier layer made of tantalum nitride (TaN), titanium nitride (TiN), or the like and an adhesion layer made of tantalum (Ta), titanium (Ti), or the like.

### SUMMARY OF THE INVENTION

According to an embodiment of the present invention, a wiring structure comprises a damascene wiring structure including a metal wiring, wherein the metal wiring is provided in direct contact with an upper surface of a barrier film (SiC(O, N) film) containing silicon (Si), carbon (C), and at least one of oxygen (O) and nitrogen (N) as constituent components.

According to another embodiment of the present invention, a wiring structure comprises a substrate, an SiC(O, N) film provided on said substrate, and a metal wiring film provided in direct contact with an upper surface of said SiC(O, N) film.

According to still another embodiment of the present invention, a semiconductor device comprises the wiring structure according to an embodiment.

According to yet another embodiment of the present invention, a method of manufacturing a wiring structure comprises providing a patterned trench structure corresponding to a wiring pattern on a substrate, providing an SiC(O, N) film on an inner wall of the trench structure, and providing a metal wiring in direct contact with the SiC(O, N) film.

According to still yet another embodiment of the present invention, a method of manufacturing a wiring structure comprises forming an SiC(O, N) film on a trench inner wall of a patterned trench structure corresponding to a wiring pattern, and providing a metal wiring in direct contact with a surface of the SiC(O, N) film on the trench inner wall.

According to yet still another embodiment of the present invention, a method of manufacturing a semiconductor device comprises each step of the method of manufacturing the wiring structure according to an embodiment as part of steps.

Other features and advantages of the present invention will be apparent from the following descriptions taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a flowchart schematically illustrating an example of steps in the manufacture of a wiring structure portion according to an embodiment of the present invention (single damascene wiring structure);

FIG. 2 shows views schematically illustrating integration in the main steps of the wiring structure portion according to the embodiment of the present invention which is made in accordance with the flowchart shown in FIG. 1;

FIG. 3 is a flowchart schematically illustrating an example of steps in the manufacture of a wiring structure portion according to another embodiment of the present invention (dual damascene wiring structure);

FIG. 4 is a flowchart schematically illustrating an example of steps to be executed next to the steps shown in FIG. 3 (dual damascene wiring structure);

FIG. 5 shows views schematically illustrating integration in the main steps of the wiring structure portion according to the embodiment of the present invention which is made in accordance with the flowcharts shown in FIGS. 3 and 4;

FIG. 6 shows views schematically illustrating integration in the main steps of the wiring structure portion according to the embodiment of the present invention which is made in accordance with the flowcharts shown in FIGS. 3 and 4;

FIG. 7 shows graphs illustrating measured data obtained by experiments (to be described later) according to the embodiment of the present invention and showing the thermal stability of a resistance/capacitance and the thermal stability of a leakage current, respectively;

FIG. 8 is a graph illustrating measured data obtained by experiments (to be described later) according to the embodiment of the present invention and showing the thermal stability of a MIS capacitor;

FIG. 9 is a graph illustrating measured data obtained by experiments (to be described later) according to the embodiment of the present invention and showing thin film formation at a MIS capacitor and a leakage current;

FIG. 10 is a flowchart schematically illustrating an example of steps in the manufacture of a wiring structure portion according to still another embodiment of the present invention (dual damascene wiring structure); and

FIG. 11 shows views schematically illustrating integration in the main steps of the wiring structure portion according to the embodiment of the present invention which is made in accordance with the flowchart shown in FIG. 10.

### DESCRIPTION OF THE EMBODIMENTS

The present inventors obtained the following findings by extensive studies. That is, upon manufacturing a wiring structure or a semiconductor device including the structure, when the heat treatment process is performed in a state in which the Ti film or TiN film used in PTL 1 or 2 is in direct contact with the CF film, fluorine diffuses from the CF film to the Ti film or TiN film, and, for example, titanium fluoride (TiF₄) is generated in the Ti film or TiN film. This may degrade the heat resistance and lead to defective products.

An embodiment of the present invention has been made in consideration of the above-described situation. An embodiment of the present invention provides a Cu wiring structure having a damascene structure that suppresses generation of a leakage current and has an excellent heat resistance and interlayer adhesion, and a method of manufacturing the same.

An embodiment of the the present invention provides a semiconductor device having the Cu wiring structure having a damascene structure that suppresses generation of a leakage current and has an excellent heat resistance and interlayer adhesion, and a method of manufacturing the same.

According to an embodiment of the present invention, it is possible to provide a wiring structure and a semiconductor device, which suppress an increase in a leakage current by preventing diffusion of fluorine from a CF(H) film that is an interlayer dielectric film when performing a heat treatment process and have an excellent heat resistance and interlayer adhesion.

Embodiments of the present invention will now be described with reference to the accompanying drawings. Note that the same reference numerals denote constituent elements having substantially the same functional arrangements throughout the specification and drawings, and a repetitive description thereof will be omitted.

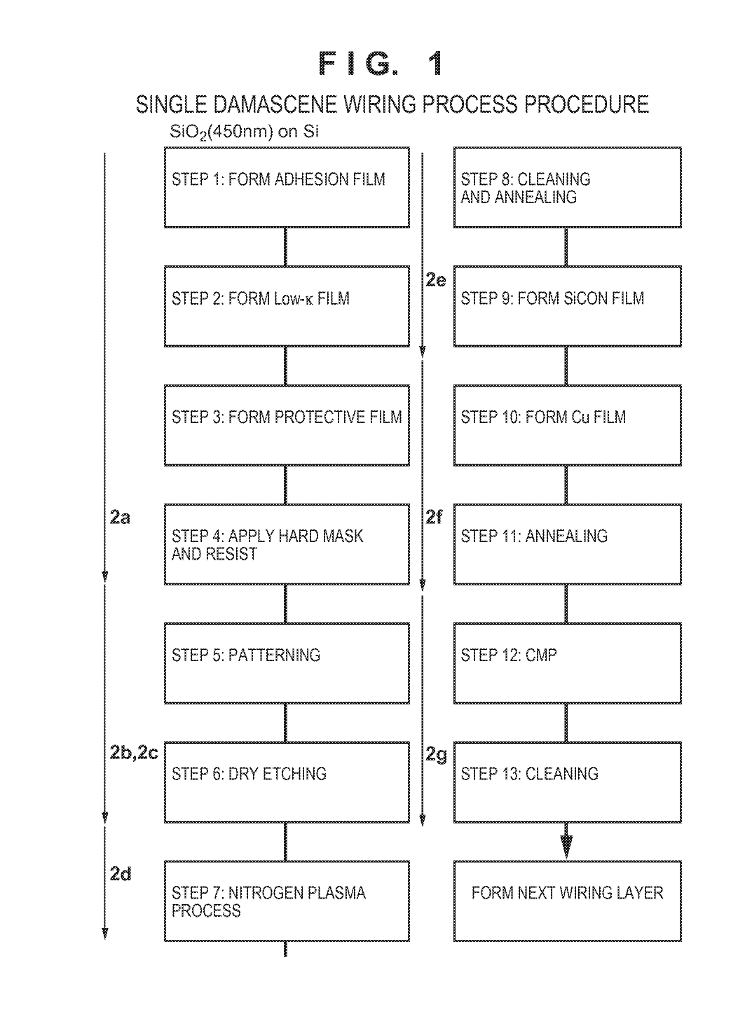

FIG. 1 is a flowchart schematically illustrating an example of steps in the manufacture of a single damascene wiring structure portion according to an embodiment of the present invention.

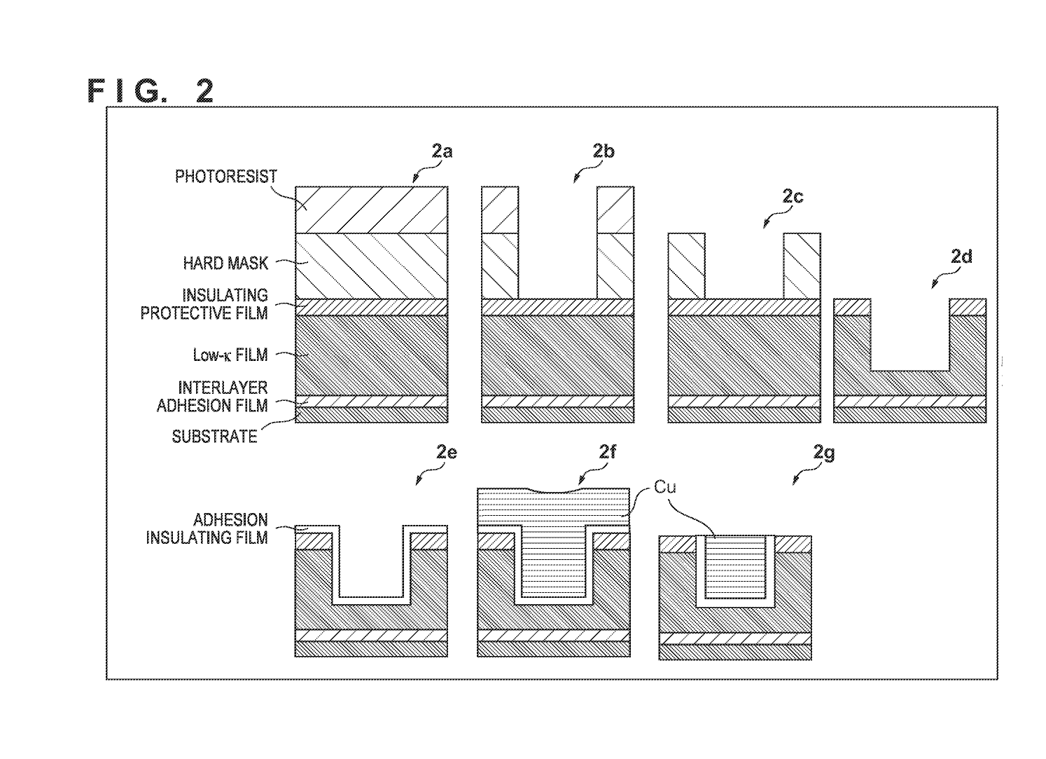

FIG. 2 schematically illustrates integration in the main steps of the wiring structure portion according to the embodiment of the present invention which is made in accordance with the flowchart shown in FIG. 1.

First, a desired appropriate Si wafer undergoes a predetermined process such as cleaning that is normally performed. The Si wafer is set at a predetermined portion of a predetermined deposition apparatus. A silicon oxide film (SiO₂ film) having a thickness of, for example, about 450 nm is formed on the surface of the Si wafer by a deposition method such as thermal oxidation or plasma oxidation. An interlayer adhesion film is formed on the thus prepared wiring structure substrate (step 1).

The adhesion film is provided to airtightly, uniformly, and firmly adhere the wiring structure substrate to another film to be provided on it. In the embodiment of the present invention, the adhesion film need not always be provided. As the adhesion film, for example, a film (to also be referred to as an “SiCN film” hereinafter) including silicon (Si), carbon (C), and nitrogen (N) is used.

The adhesion film preferably has a function of excellent electrical insulating properties as well as the above-described adhesion function. The adhesion film also preferably has an excellent film strain resistance (stress resistance) so as to attain a resistance to heat load during the manufacturing process of the wiring structure or a time-rate change in long-term use. As such a film, for example, an SiCN film having an amorphous structure is preferably used.

Such a film is formed to a thickness of 15 nm by, for example, supplying trimethylsilane (40), Ar (500), and N₂ (50) into the film deposition chamber of a normal plasma deposition apparatus and performing a process at a pressure 130 mTorr, a substrate temperature of 350° C., and a plasma excitation power of 2,500 W. A parenthesized numerical value indicates a gas flow rate whose unit is sccm.

Next, as shown in FIG. 1, a low-κ film is formed on the adhesion film by a deposition method using a plasma generated by, for example, a radial line slot antenna method (step 2). The low-κ film is a film having a low dielectric constant. In the embodiment of the present invention, the low-κ film is provided as needed. As the low-κ film, for example, a film (to also be referred to as a “CFx film” hereinafter) mainly containing carbon (C) and fluorine (F) is preferably used. A fluorine-added carbon film is more preferable. Alternatively, an interlayer dielectric film made of a carbon film (to also be referred to as a “CF(H) film” in the present application) containing at least fluorine (F) and hydrogen (H) as needed as constituent components may be used as the low-κ film.

The CFx film is formed by, for example, the same deposition process using the same deposition apparatus as the SiCN film. The deposition conditions at that time are, for example, C₅F₈ (200 sccm), Ar (70 sccm), a substrate temperature of 350° C., a pressure of 25 mTorr, and a plasma excitation power of 1,400 W. The CFx film is formed to a thickness of 400 nm.

Next, a protective film is formed on the low-K film (step 3). The protective film formed in step 3 is preferably, for example, a film having an amorphous structure and excellent electrical insulating properties. As such a protective film, a film (to also be referred to as an “SiCO film” hereinafter) containing silicon (Si), carbon (C), and oxygen (O) is preferably used.

The SiCO film is formed by, for example, a predetermined deposition process using a deposition apparatus similar to that for the SiCN film. The deposition conditions at that time are, for example, trimethylsilane (15 sccm), O₂ (100 sccm), C₂H₆ (44 sccm), Ar (20 sccm), a substrate temperature of 350° C., a pressure of 60 mTorr, a plasma excitation microwave power of 2,000 W, and an RF bias power of 30 W. The SiCO film is formed to a thickness of 400 nm. The RF bias power is also used to accelerate ions generated by plasma excitation.

As indicated by 2a of FIG. 2, a hard mask and a resist are applied on the protective film formed in step 3 (step 4).

Then, patterning is performed, and dry etching is performed to form a trench structure having a wiring pattern (steps 5 and 6). Integration of the wiring structure at that time is indicated by 2b of FIG. 2. Patterning is executed by performing exposure at about 420 J using an exposure apparatus having, for example, a KrF light source.

After that, an N₂ plasma process (step 7) and cleaning and annealing (step 8) are performed, thereby forming a wiring structure indicated by 2d of FIG. 2.

Next, an electrical insulating film having high adhesion is formed along the inner wall and surface of the trench structure, as indicated by 2e of FIG. 2 (step 9). The insulating film formed in step 9 constitutes the characteristic feature of the embodiment of the present invention, and surprisingly solves the conventional problems at once by directly firmly adhering to a Cu wiring, as will be described later.

Such an insulating film can be made of a material mainly containing silicon (Si), carbon (C), oxygen (O), and nitrogen (N), and can have a desired function with excellent film strain resistance (stress resistance) and electrical insulating properties by appropriately selecting the composition ratio in accordance with the requirement.

The amount of carbon (C) in the film is preferably 5 to 40 mass % with respect to the total film amount. This carbon (C) amount allows the film to have a resistance to heat load during the manufacturing process of the wiring structure or a time-rate change in long-term use. Especially, when the density distribution of oxygen (O) and/or nitrogen (N) in the film thickness direction is increased in the growing direction of the layer, the characteristic can further be improved. The density distribution can be changed stepwise or continuously. A film having an amorphous structure is preferably used because a more excellent film strain resistance (stress resistance) can be obtained.

Such a film is preferably formed under conditions including a substrate temperature of 350° C., trimethylsilane (3MS) (14 sccm), C₂H₆ (44 sccm), O₂ (100 sccm), N₂ (25 sccm), a pressure of 60 mTorr, a plasma excitation microwave power of 2,000 W, and an RF bias power of 30 W using an apparatus (MEP1) available from Tokyo Electron.

For example, a silicon-based insulating film formed by a deposition method using a plasma generated by microwave excitation such as a radial line slot antenna method is also usable.

As for other conditions when depositing the insulating film in step 9, for example, TMS (trimethylsilane), O₂ (oxygen), and C₄H₆ (butine) are supplied into a plasma deposition apparatus including a radial line slot antenna under conditions of a substrate temperature of 350° C., a microwave power of 2.5 kW, and a pressure of 50 mTorr, and deposition is performed.

Copper (Cu) is buried in the trench portions of the wiring structure (2e of FIG. 2) formed by step 9, as indicated by 2e of FIG. 2 (step 10). To bury copper (Cu) in the trench portions of the wiring structure, first, for example, a seed layer of copper (Cu) is formed by sputtering (PVD). After that, copper (Cu) is buried in the trench portions by electroplating. As for the manufacturing conditions at that time, for example, electroplating is performed using a current of 12 A, and the conditions of PVD are 15 kW, RF: 400 W, and a pressure: 0.7 Pa.

After that, annealing (step 11), CMP (step 12), and cleaning (step 13) are executed.

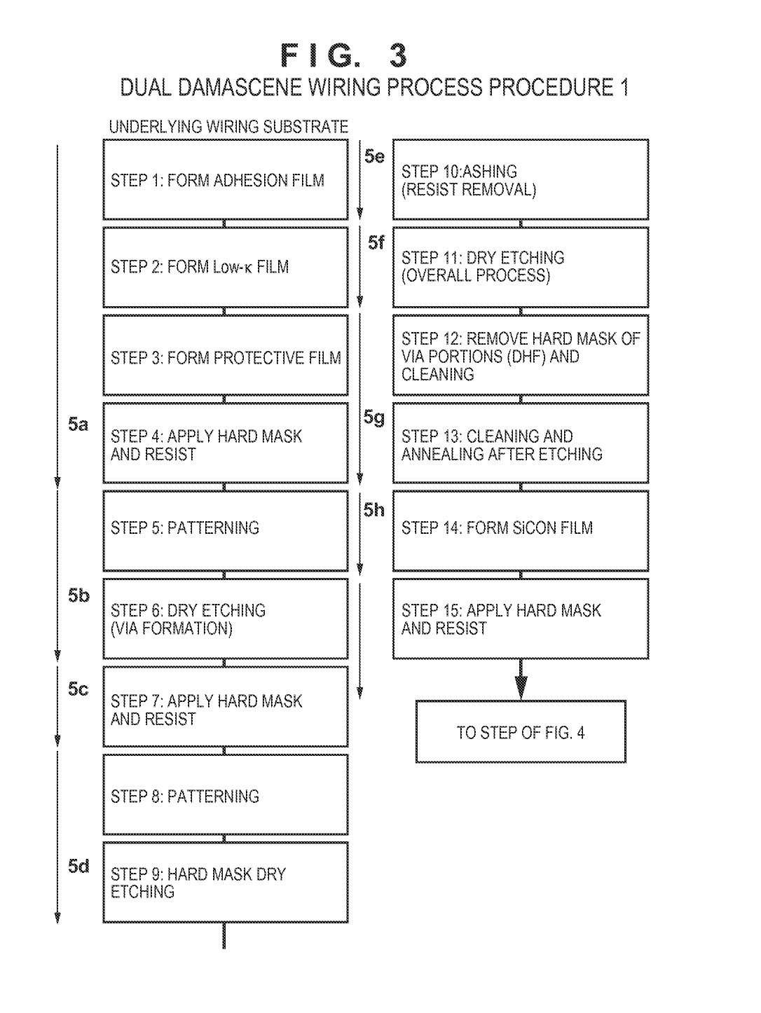

Table 1 shows examples of the manufacturing apparatus, drug solutions, and the like usable in the manufacturing step shown in FIG. 3.

In this way, a single damascene wiring structure is formed.

As the wiring material, Cu is preferably used to implement a high-speed operation and an extra fine structure. In the embodiment of the present invention, metals other than Cu, Cu alloys, aluminum (Al), alloys thereof, and metal silicides are also usable.

TABLE 1

| | | | Film | Reagent |
|---|---|---|---|---|
| Step | Process procedure | Apparatus name | thickness | solution |
| 1 | deposition of | MEP1 (available | 15 nm | |
| | adhesion film | from TEL) | | |
| | (SiCN) | | | |
| 2 | deposition of CFx | MEP3 (available | 400 nm | |
| | | from TEL) | | |
| 3 | deposition of | MEP1 (available | 100 nm | |
| | protective film | from TEL) | | |
| | (SiCO) | | | |
| 4 | hard mask | ACT8 (available | 200 nm | MIBK + H |
| | application | from TEL) | | (available |
| | | | | from Ube |
| | | | | Industries) |
| | | | | (SiO₂- |
| | | | | based) |
| 5 | resist | available from | | TDUR-P3116 |
| | application | TEL | | EM (available |
| | | | | from |
| | | | | Tokyo Ohka |
| | | | | Kogyo) |
| 6 | patterning | FPA3000 | | |
| | | (available from | | |
| | | Canon) | | |
| 7 | dry etching | RLSA (available | | |
| | | from TEL) | | |
| 8 | N₂ plasma | RLSA (available | | |
| | process | from TEL) | | |
| 9 | cleaning after | single wafer | | DHF 0.5% |
| | etching | cleaner | | |
| | | (available from | | |
| | | Realize-AT) | | |
| 10 | annealing | ACT8 (available | | |
| | | from TEL) | | |
| 11 | deposition of | MEP1 (available | 15 nm | |
| | adhesion | from TEL) | | |
| | insulating | | | |
| | liner film | | | |
| | (SiCON) | | | |
| 12 | seed Cu | Entron | 150 nm | |
| | | (available from | | |
| | | Ulvac | | |
| 13 | electroplating Cu | ECP200 | 500 nm | |
| | | (available from | | |
| | | Ebara) | | |
| 14 | anneal | ACT8 (available | | |
| | treatment | from TEL) | | |
| 15 | CMP | APD-800 | | |
| | | (available from | | |
| | | ARACA Inc) | | |
| 16 | cleaning after | brush cleaner | | Clean-100 |
| | CMP | RC300 | | (available |
| | | (available from | | from Wako |
| | | Realize-AT) | | Chemicals) |
| | | | | (citric acid- |
| | | | | based) |

A damascene Cu wiring structure generally used in a semiconductor device is a so-called dual damascene structure in which a plurality of Cu wiring layers are stacked. As an example of the present invention, a case where two Cu wiring structures are stacked and connected by via wirings (so-called double damascene wiring structure) will be described next.

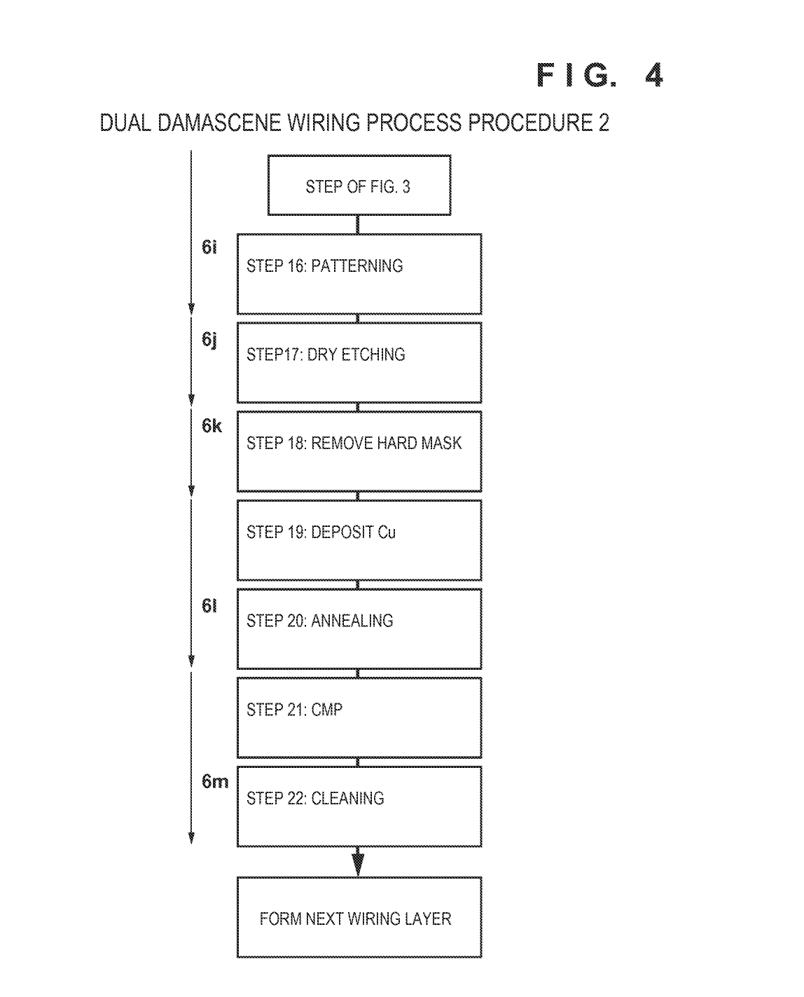

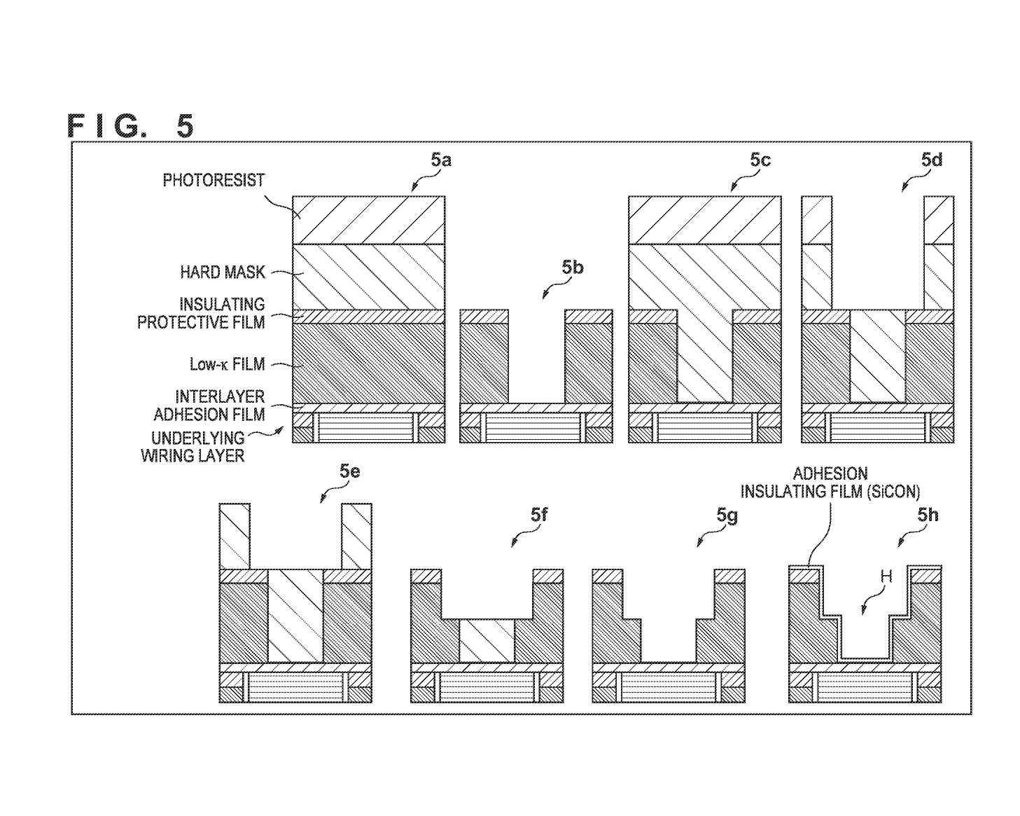

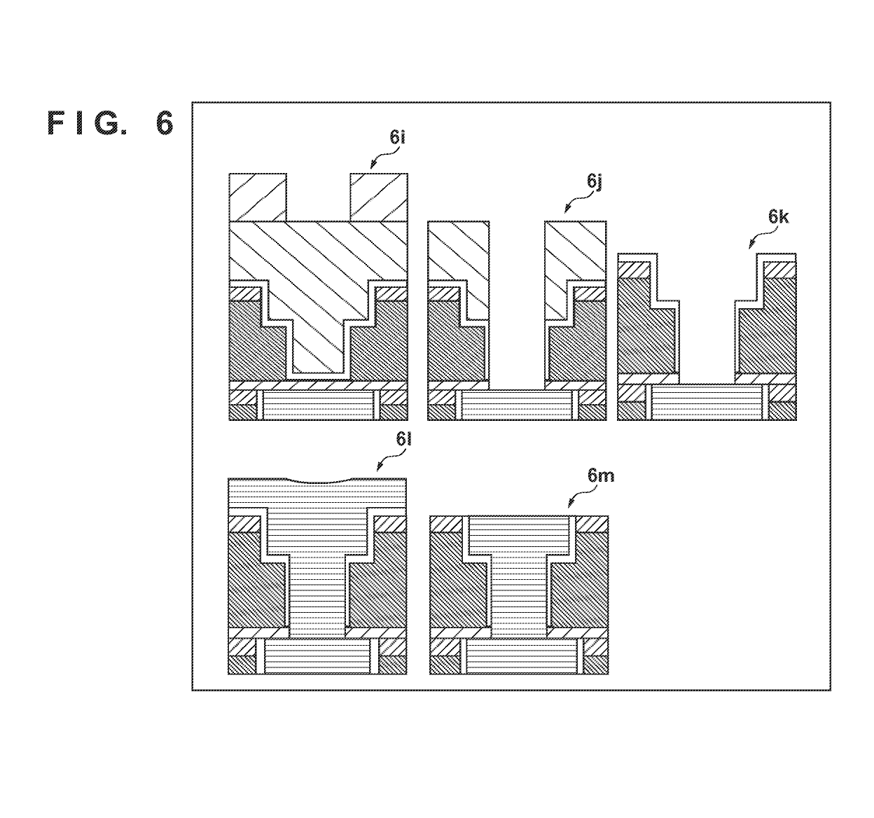

FIGS. 3 to 6 are explanatory views showing steps in the manufacture of damascene Cu wiring structures arranged in two layers. FIGS. 3 and 4 show the process procedure, and FIGS. 5 and 6 show integration of the wiring structure in the process procedure.

As shown in FIGS. 3 and 4, after the Cu wiring structure (underlying wiring layer) of the first layer is formed, an interlayer adhesion film that is a CFx film having electrical insulating properties is formed on the surface of the underlying wiring structure by, for example, a deposition method using a plasma excited by a radial line slot antenna.

Next, a wiring trench structure including trenches and via holes having a damascene structure is formed on the surface of the interlayer adhesion film by, for example, photolithography and reactive ion etching (RIE).

Next, an SiCON film as an adhesive electrical insulating film is formed so as to cover the inner surface of the wiring trench structure portion, as indicated by 5h of FIG. 5. The SiCON film is formed by, for example, a deposition method using a plasma excited by a radial line slot antenna (RLSA), as described above (step 14 of FIG. 3).

As shown in FIGS. 3 and 4, steps 14 to 19 are executed to remove the SiCON film formed on the bottom surface of the wiring trench structure. More specifically, in the wiring trench structure, SiCON films formed on the bottom surfaces of the trenches and the bottom surfaces of the via holes are removed. The SiCON film is left only on the side surfaces (side walls) of the trenches and via holes (6k of FIG. 6).

Next, as indicated by 6l and 6m of FIG. 6, a Cu conductive layer is formed on the entire surface of the wiring trench structure so as to fill the gaps in the wiring trench structure. The Cu conductive layer need not always be made of pure Cu, and may be made of a Cu alloy.

As indicated by 6m of FIG. 6, the Cu conductive layer is removed from the upper surface of the insulating protective film by CMP while leaving the Cu conductive layer inside the wiring trench structure (steps 15 and 16 of FIGS. 3 and 4).

Note that in this embodiment, a case has been described where the present invention is applied to a Cu wiring structure having a double damascene (two-layer) structure. However, the present invention is also applicable to a case where a plurality of Cu wiring structures including three or more layers are stacked, as a matter of course.

Steps in the manufacture of a Cu wiring structure having a double damascene structure according to an example different from that shown in FIGS. 3 to 6 will be described next.

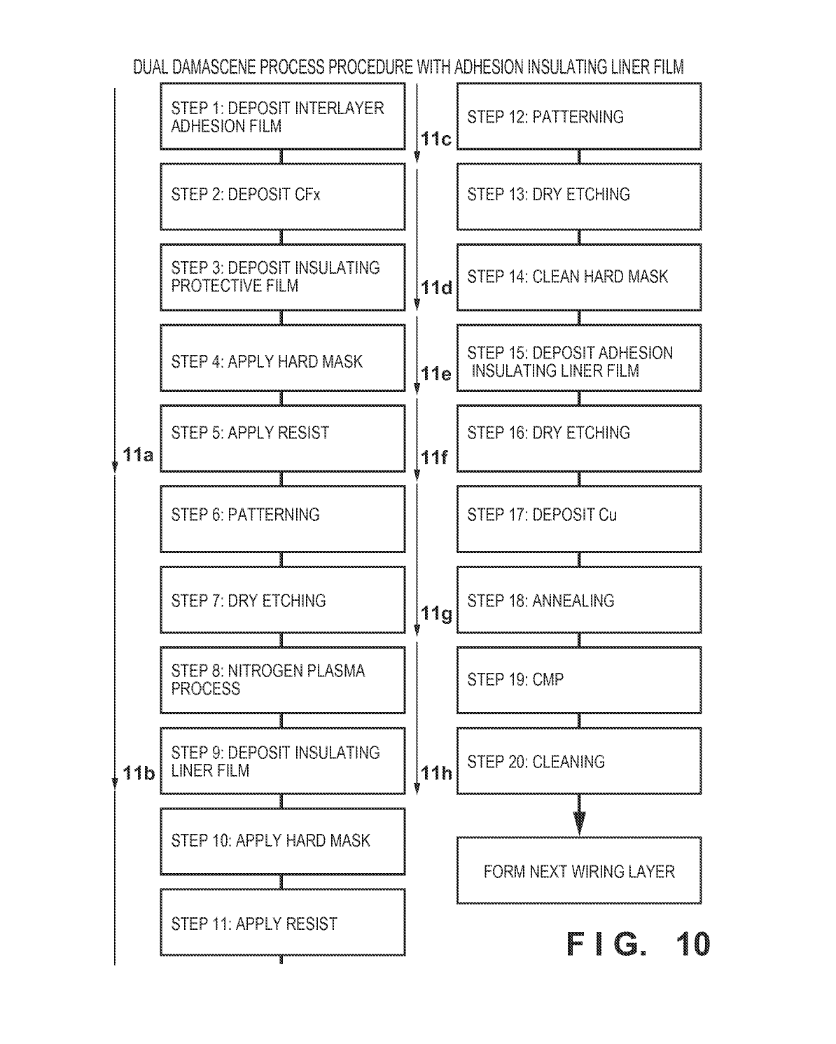

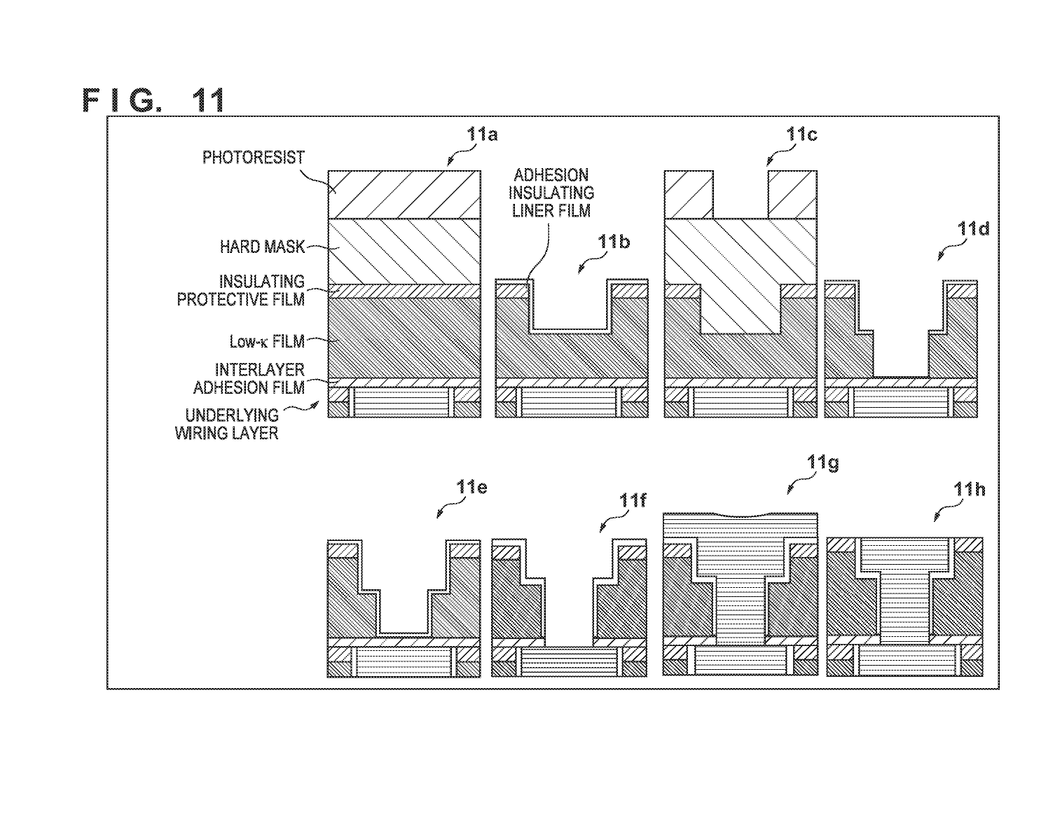

FIGS. 10 and 11 are explanatory views showing steps in the manufacture of a two-layer damascene Cu wiring structure according to the second example. FIG. 10 shows the process procedure, and FIG. 11 shows integration of the wiring structure in the process procedure. Concerning FIGS. 10 and 11, the same or similar structures and steps as in the example shown in FIGS. 3 to 6 will be described only briefly, or a description thereof will be omitted.

The example shown in FIGS. 10 and 11 is largely different from the example shown in FIGS. 3 to 6 in that an adhesion insulating liner film (SiCNO film) is provided in the steps up to step 9 shown in FIG. 10, as indicted by lib of FIG. 11, and structures indicated by 11d, 11e, and 11f of FIG. 11 are formed in steps 14 to 16 of FIG. 10.

As indicated by 11d of FIG. 11, the adhesion insulating liner film (SiCNO) is partially removed from the inner side walls (the lower portion of the hole). Then, an adhesion insulating liner film (SiCNO) is formed on the removed portion again in step 15 of FIG. 10, as indicated by 11e of FIG. 11.

The remaining steps are performed in accordance with almost the same manufacturing conditions and procedures as in the example shown in FIGS. 3 to 6.

[Experiment 1]

Five MIS capacitor samples (sample Nos. 1 to 5) were made in accordance with the following conditions. The leakage current was measured, and the thermal stability and SiCNO film thickness dependence were confirmed. The samples were measured before the start of annealing and at the timings when annealing progressed 1 hr and 2 hrs.

Process conditions and measurement conditions were as follows.

(1) aCSiON-Liner (15 nm) Deposition Conditions:

Step 1: Formation of aCSi

200° C., 3MS/Ar: 15/19.5 sccm, 60 mTorr, 2,000 W/RF-30 W, 5 sec

Step 2: Formation of aCSiON

200° C., 3 MS/C₂H₆/O₂/N₂: 15/44/100/25 sccm, 60 mTorr, 2,000 W/RF-30 W, 40 sec

(2) Measurement Conditions

Name of resistance and leakage current measurement apparatus:

Aglient 4156C precision semiconductor parameter analyzer

Resistance measurement: kelvin pattern, voltages of 0 to 100 mV are applied, and the resistance is calculated based on the measured current.

Leakage current: comb pattern, voltages of 0 to 25 V are applied, and an inter-wiring leakage current is measured.

Name of capacitance measurement apparatus: (HP4284A precision LCR meter)

Capacitance: comb pattern, 1 MHz, 26 mV bias

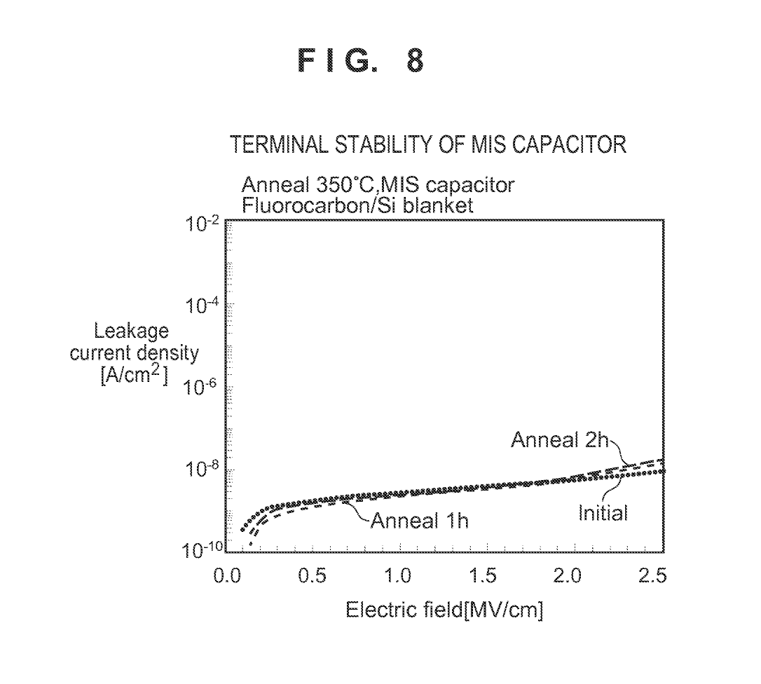

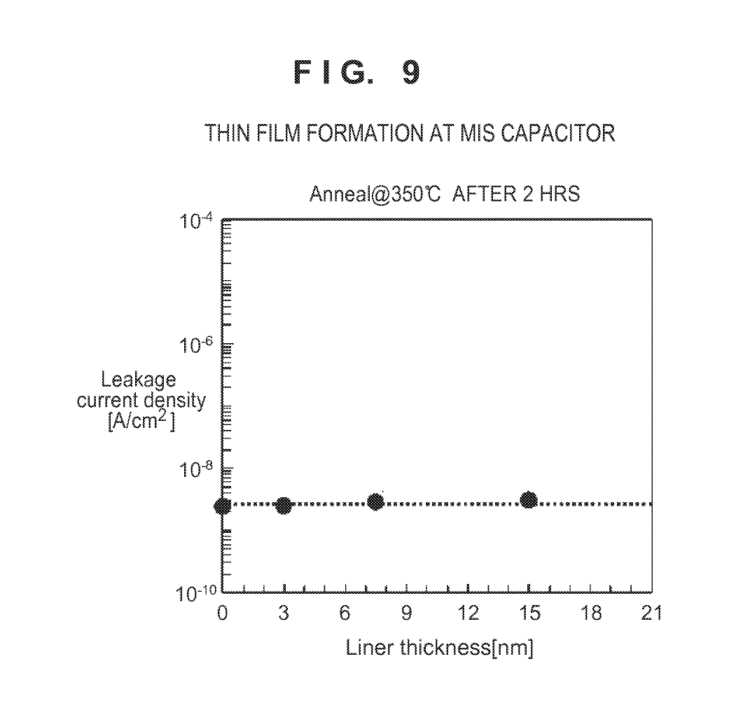

FIGS. 8 and 9 show the results.

### EXAMPLE 1

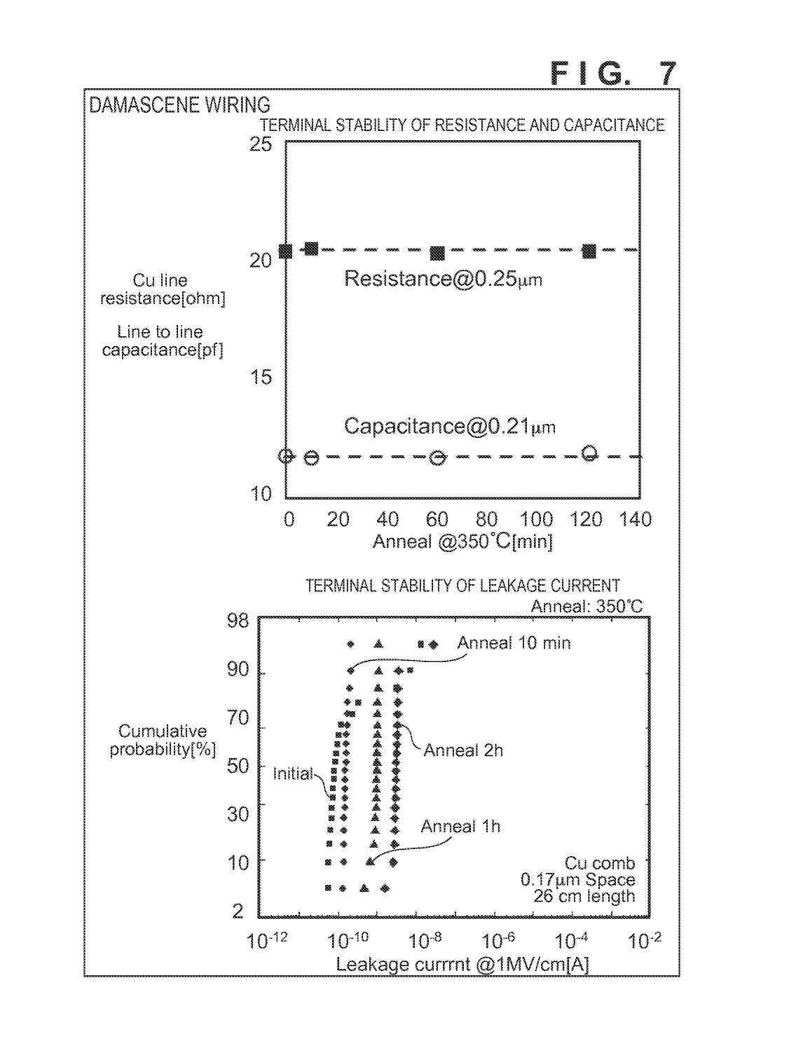

A single damascene wiring structure was made in accordance with the procedure shown in FIG. 1 under the following process conditions, and the heat characteristics of the leakage current, electrical resistance, and capacitance were checked. FIG. 7 shows the results.

The process conditions in the steps were as follows.

Step 1: Deposition of Adhesion Film (SiCN)

350° C., 3MS/Ar/N2: 40/500/50 sccm, 130 mTorr, 2,500 W, 15 nm

Step 2: Deposition of CFx

350° C., C₅F₈/Ar: 200/70 sccm, 25 mTorr, 1,400 W, 400 nm

Step 3: Deposition of Protective Film (SiCO)

350° C., 3MS/O2/C₂H₆/Ar: 15/100/44/20 sccm, 60 mTorr, 2,000 W, RF-30 W

Step 4: Hard Mask and Resist Application

Step 5: Patterning

KrF, 420 J

Step 6: Dry Etching

CF₄/C₅F₈/N₂/Ar: 60/5/10/100 sccm, 100 mTorr, 2,000 W, RF-280 W

Step 7: N₂ Plasma Process

N₂/Ar: 80/20 sccm, 100 mTorr, 2 kW, RF-150 W

Step 8: Cleaning and Annealing After Etching

HF: 0.5%, spin speed: 500 rpm, 1 min

350° C., N₂, 10 min

Step 9: Deposition of Adhesion Insulating Liner film (SiCON)

350° C., 3MS/C₂H₆/O₂/N₂: 14/44/100/25 sccm, 60 mTorr, 2,000 W, RF-30 W

Step 10: Cu Deposition

PVD: 15 kW, RF: 400 W, 0.7 Pa, 150 nm

Electroplating: 500 nm

Step 11: Anneal Treatment

260° C., N₂, 4 min

Step 12: CMP

10.34 kPa, Cu: wafer/platen: 148/25 rpm

Step 13: Cleaning After CMP

5.5 kPa, brush/wafer: 400/150 rpm

Next, a wiring layer was formed.

The measurement conditions were the same as described above.

### EXAMPLE 2

A Cu wiring structure having a double damascene structure was made in accordance with the manufacturing steps shown in FIGS. 10 and 11. Manufacturing conditions in the main steps will be described below. The conditions in other steps were the same as those in corresponding steps of Example 1.

When the heat dependence of the inter-wiring leakage current was measured, the obtained wiring structure exhibited an inter-wiring leakage current characteristic with excellent thermal stability as compared to a conventional type and thus proved to be highly practical.

Step 1: Deposition of Interlayer Adhesion Film (CiCN)

350° C., 3MS/Ar/N₂: 40/500/50 sccm, 130 mTorr, 2,500 W, 15 nm

Step 2: Deposition of CFx

350° C., C₅F₈/Ar: 200/70 sccm, 25 mTorr, 1,400 W, 400 nm

Step 3: Deposition of Insulating Protective Film (SiCO)

350° C., 3MS/O₂/C₂H₆/Ar: 15/100/44/20 sccm, 60 mTorr, 2,000 W, RF-30 W

Step 7: Dry Etching

CF₄/C₅F₈/N₂/Ar: 60/5/30/100 sccm, 100 mTorr, 2,000 W, RF-250 W

Step 8: Nitrogen Plasma Process

N₂/Ar: 80/20 sccm, 100 mTorr, 2 kW, RF-150 W

Step 9: Deposition of Adhesion Insulating Liner film

350° C., 3MS/C₂H₆/O₂/N₂: 14/44/100/25 sccm, 60 mTorr, 2,000 W, RF-30 W

Step 12: Patterning

KrF, 420 J

Step 13: Dry Etching

CF₄/C₅F₈/N₂/Ar: 60/5/30/100 sccm, 100 mTorr, 2,000 W, RF-250 W

Step 14: Hard Mask Cleaning

HF: 0.5%, spin speed: 500 rpm

Step 15: Deposition of Adhesion Insulating Liner Film

350° C., 3MS/C₂H₆/O₂/N₂: 14/44/100/25 sccm, 60 mTorr, 2,000 W, RF-30 W

Step 16: Dry Etching

CF₄/C₅F₈/N₂/Ar: 60/5/30/100 sccm, 100 mTorr, 2,000 W, RF-250 W

Step 17: Cu Deposition

PVD: 15 kW, RF: 400 W, 0.7 Pa, 150 nm

Electroplating: 500 nm, 12 A

Step 18: Annealing

260° C., N₂, 4 min

Step 19: CMP

5.5 kPa, brush/wafer: 400/150 rpm

The embodiments of the present invention have been described above. However, the present invention is not limited to the illustrated forms. Those skilled in the art can obviously hit upon various changes and modifications within the spirit described in the appended claims, which can be understood to belong to the technical scope of the present invention, as a matter of course.

As is apparent from the above-described experiments and examples, even when the SiCON film that is the characteristic feature of the embodiment of the present invention is provided between the CFx film and the Cu wiring portion in a direct contact state, diffusion of fluorine (F) from the CFx film and diffusion of copper (Cu) from the Cu wiring portion can reliably be prevented, and the constituent atoms of the SiCON film do not diffuse from the film.

Hence, regardless of the simple layer structure, it is possible to reliably suppress diffusion of fluorine (F) from the CFx film, which occurs in a conventional semiconductor device, suppress an increase in the leakage current when performing a heat treatment process such as annealing for the semiconductor device, and avoid occurrence of defective devices and the like, as is apparent.

The embodiment of the present invention is applicable to a wiring structure, a method of manufacturing the same, and a semiconductor device including the wiring structure and a method of manufacturing the semiconductor device, and from the industrial point of view, can greatly contribute to the cost efficiency and resource savings.

The present invention is not limited to the above embodiments and various changes and modifications can be made within the spirit and scope of the present invention. Therefore, to apprise the public of the scope of the present invention, the following claims are made.

1. A wiring structure comprising a damascene wiring structure including a metal wiring, wherein the metal wiring is provided in direct contact with an upper surface of a barrier film (SiC(O, N) film) containing silicon (Si), carbon (C), and at least one of oxygen (O) and nitrogen (N) as constituent components.

2. A wiring structure comprising a substrate, an SiC(O, N) film provided on said substrate, and a metal wiring film provided in direct contact with an upper surface of said SiC(O, N) film.

3. A semiconductor device comprising the wiring structure according to claim 1.

4. A semiconductor device comprising the wiring structure according to claim 2.

5. A method of manufacturing a wiring structure, comprising providing a patterned trench structure corresponding to a wiring pattern on a substrate, providing an SiC(O, N) film on an inner wall of the trench structure, and providing a metal wiring in direct contact with the SiC(O, N) film.

6. A method of manufacturing a wiring structure, comprising forming an SiC(0, N) film on a trench inner wall of a patterned trench structure corresponding to a wiring pattern, and providing a metal wiring in direct contact with a surface of the SiC(O, N) film on the trench inner wall.

7. A method of manufacturing a semiconductor device, comprising each step of the method of manufacturing the wiring structure according to claim 5 as part of steps.

8. A method of manufacturing a semiconductor device, comprising each step of the method of manufacturing the wiring structure according to claim 6 as part of steps.
